(19) United States
(12) Patent Application Publication
(10) Pub. No.: US 2006/0108627 A1
(43) Pub. Date: May 25, 2006

(54) NAND flash memory devices including multi-layer memory cell transistor structures and methods of fabricating the same

(75) Inventors: Jeong-Hyuk Choi, Gyeonggi-do (KR); Yun-Seung Shin, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/286,501

(22) Filed: Nov. 23, 2005

(30) Foreign Application Priority Data
Nov. 24, 2004 (KR) 2004-0097003

(51) Int. Cl. H01L 29/76

(52) U.S. Cl. 257/314

(57) ABSTRACT

An integrated circuit memory device on a multi-layer substrate includes first and second selection transistors, a first plurality of serially connected memory cell transistors on a first substrate layer, and a second plurality of serially connected memory cell transistors on a second substrate layer. The first plurality of serially connected memory cell transistors are serially connected between the first and second selection transistors. The second plurality of serially connected memory cell transistors are also serially connected between the first and second selection transistors.

### CROSS-REFERENCE TO RELATED APPLICATIONS

This application claims priority under 35 U.S.C. § 119 from Korean Patent Application 10-2004-0097003 filed on Nov. 24, 2004, the disclosure of which is hereby incorporated by reference herein in its entirety.

### BACKGROUND OF THE INVENTION

The present invention relates to semiconductor devices, and more particularly, to flash memory devices and methods of fabricating the same.

Many electronic devices and/or appliances employ semiconductor devices. The semiconductor devices may include electronic elements such as transistors, resistors, and/or capacitors. These electronic elements may be integrated on semiconductor substrates. For example, electronic devices such as computers and digital cameras may include memory chips for storing information and processing chips for processing information. The memory chips and/or processing chips may include electronic elements integrated on semiconductor substrates.

Semiconductor devices have become highly integrated to satisfy consumer demands regarding performance and cost. To provide such high-integration, there may be a need to reduce the size of semiconductor devices, which may be dependent on advancements in semiconductor fabrication technologies (for example, photolithography techniques). As such, the integration of semiconductor devices may be limited due to expenses and development time associated with advancements in fabrication technologies.

However, even though fabrication technologies may be advancing, it may be difficult to reduce channel length in transistors, as leakage current in the transistor may increase as the size of the channel is reduced. This leakage current is a type of short channel effect due to the decrement decreasing channel length. Because of leakage current, it may be difficult to determine whether a cell transistor in a flash memory device is programmed. Accordingly, if leakage current problems are not addressed, it may be difficult to reduce a unit cell area of flash memory devices.

In NAND flash memory devices, there may be other technical limitations, for example, related to minimum sensible current. NAND flash memory may include a string selection transistor, a ground selection transistor, and a plurality of cell transistors therebetween. An example of NAND flash memory is described in “A 2 Gb NAND Flash Memory With 0.044 μm² Cell Size Using 90 nm Flash Technology” IEDM 2002, pp. 919-922, by Kim et al. In accordance with this NAND flash memory structure, the greater the number of cell transistors between the two selection transistors, the smaller the occupied area of the cell array regions. Furthermore, as the occupied area becomes smaller, the integration of the NAND flash memory device can be increased.

However, when the number of cell transistors serially connected between selection transistors is increased, resistance may also be increased during a read operation. As a result, the read current may be smaller than the minimum sensible current in a sensing circuit. In this case, the number of cell transistors between the selection transistors may be limited to 32 in many existing NAND flash memory devices. Accordingly, the minimum sensible current may be a major obstacle in reducing the occupied area in NAND flash memory devices.

### SUMMARY OF THE INVENTION

According to some embodiments of the present invention, a semiconductor device is provided including semiconductor patterns having a multi-layered structure. The semiconductor device may include a semiconductor substrate, lower transistors on the semiconductor substrate, and a plurality of semiconductor patterns on the semiconductor substrate and the lower transistors. An upper transistor structure may be on the semiconductor patterns, and one or more insulating layers may be between the semiconductor substrate and the semiconductor patterns. An interconnection structure may extend through the insulating layers to electrically connect the lower transistors and the upper transistor structure.

In some embodiments, the semiconductor substrate may be a single crystalline silicon layer. In addition, the semiconductor patterns may be formed to different heights to form the multi-layered structure.

In other embodiments, the upper transistor structure may include a plurality of memory cell gate electrodes arranged on an upper portion of the semiconductor pattern, gate insulating layers between the memory cell gate electrodes and the semiconductor pattern, and memory cell impurity regions formed on the semiconductor pattern between the memory cell gate electrodes and the semiconductor pattern. The memory cell gate electrode may include a floating gate electrode, an intergate insulating pattern, and a control gate electrode, which may be sequentially stacked. In addition, epitaxial seed patterns may vertically extend from the semiconductor substrate adjacent the semiconductor patterns.

In some embodiments, a thickness of the semiconductor patterns may be thinner than that of the semiconductor substrate. Also, a thickness of the memory impurity regions formed at a predetermined region of the semiconductor pattern may be the same as that of the semiconductor pattern. In other embodiments, the thickness of the memory impurity region may be thinner than that of the semiconductor pattern.

In addition, the lower transistors may include a plurality of memory cell transistors and/or a plurality of function transistors.

According to other embodiments of the present invention, a semiconductor device may include a semiconductor substrate having a cell array region and a peripheral circuit region, selection lines arranged on the cell array region of the semiconductor substrate, a plurality of semiconductor patterns arranged on the cell array region of the semiconductor substrate where the selection lines are formed, and a plurality of word lines arranged on an upper portion of the semiconductor patterns and running parallel to the selection lines. Memory impurity regions may be formed in the semiconductor patterns between the word lines. Substrate impurity regions may be formed in the semiconductor substrate at both sides of the selection lines. Moreover, insulating layers covering the word lines and the selection lines may be arranged between the semiconductor substrate and the semiconductor patterns. The memory impurity regions may be electrically connected to the substrate impurity region by an interconnection structure.

In some embodiments, the semiconductor device may further include epitaxial seed patterns and a plurality of bit lines. The epitaxial seed patterns may vertically extend from the semiconductor substrate toward the semiconductor patterns, and the plurality of bit lines may be arranged on the insulating layer to cross over the word lines. The epitaxial seed patterns may be perpendicular to the bit lines.

In other embodiments, high voltage transistors and low voltage transistors may be arranged in the peripheral circuit region. The high voltage transistors may have a greater thickness than the low voltage transistors.

According to still other embodiments of the present invention, a semiconductor device may include a semiconductor substrate having a cell array region and a peripheral region, a string selection transistor and a ground selection transistor formed in the cell array region of the semiconductor substrate, a memory cell transistor structure having at least one layer arranged on an upper portion of the semiconductor substrate where the string and ground selection transistors are formed, a plurality of bit lines arranged on an upper portion of the memory cell transistor structure, and an interconnection structure. The interconnection structure may electrically connect the string and ground selection transistors and the bit line. The memory cell transistor structure may include a plurality of semiconductor patterns and a plurality of memory cell transistors formed at a predetermined region of the semiconductor patterns.

In some embodiments, the memory cell transistor structure may include word lines including a floating gate electrode, a gate insulating pattern, and a control gate electrode. The memory cell transistor structure may further include a memory gate insulating layer between the word lines and the semiconductor pattern, and memory impurity regions in the semiconductor pattern between the word lines.

In other embodiments, the memory impurity regions may have the same thickness as the semiconductor pattern. As such, charges stored in a predetermined memory cell transistor selected by a predetermined bit line and a predetermined word line may be removed by applying 0 V to the predetermined bit line, applying an erase voltage sufficient to discharge charges stored in the floating gate electrode through the gate insulating pattern toward the control gate electrode to a predetermined word line, applying a voltage capable of turning on the string selection transistor to a gate of the string selection transistor, and applying a voltage capable of turning on the memory transistor to a word line of a memory transistor between the string selection transistor and the predetermined word line. For example, the erase voltage may be about −10 V to about −25 V, the voltage capable of turning on the string selection transistor may be about 1 V to about 10 V, and the voltage capable of turning on the memory transistor may be about 1 V to about 10 V.

In some embodiments, the thickness of the memory impurity regions may be thinner than that of the semiconductor pattern. As such, a predetermined memory cell transistor selected by a predetermined bit line and a predetermined word line may have a voltage difference sufficient for a charge stored in a floating gate electrode to be discharged through the memory gate insulating layer to the semiconductor pattern by applying 0 V to the predetermined word line and applying a predetermined erase voltage to the semiconductor pattern. Charges stored in the memory transistor connected to the predetermined word line may be removed by applying the erase voltage to non-selected word lines.

According to further embodiments of the present invention, a method of fabricating a semiconductor device may include forming multi-layered semiconductor patterns. More specifically, the method may include forming lower transistors at a predetermined region of a semiconductor substrate, repeatedly performing a process for forming a memory cell transistor structure (including forming a lower insulating layer, semiconductor patterns, upper transistors, and an interconnection structure) more than at least two times to form a memory cell transistor structure having at least one layer on a structure where the lower transistors are formed. The method may further include forming an interconnection structure connected to the lower transistors and the memory cell transistor structure.

In some embodiments, the semiconductor patterns may be formed by patterning the lower insulating layer to expose a predetermined region of the semiconductor substrate, and growing a semiconductor layer from the exposed semiconductor substrate using an epitaxial growth technique. The semiconductor layer may be formed to expose an upper surface of the lower insulating layer by planarizing the semiconductor layer and then patterning the planarized semiconductor layer.

In other embodiments, the the semiconductor layer may be epitaxially grown by growing a single crystalline silicon layer at a temperature of about 800° C. using Dichlorosilane (DCS) and a hydrochloric acid, and stabilizing the grown single crystalline structure through a thermal process. The semiconductor layer may be grown to a thickness greater than the lower insulating layer. In addition, the DCS and hydrochloric acid may be supplied at a flow rate of approximately 2:1.

In some embodiments, the upper transistors may be formed by forming a memory device isolation layer defining memory active regions at a predetermined region of the semiconductor pattern, forming a gate insulating layer on the memory active region, forming a memory cell gate electrode crossing over the memory active regions on the semiconductor pattern having the memory gate insulating layer, and performing an ion implantation process using the memory cell gate electrode as a mask to form memory impurity regions in the memory active region between the memory cell gate electrodes.

In other embodiments, the memory device isolation layer may have a thinner thickness than the semiconductor patterns. The memory impurity regions may have a thinner thickness than the memory device isolation layer.

In some embodiments, the thickness of the memory device isolation layer and memory impurity region may be the same as that of the semiconductor patterns. As such, the interconnection structure may be formed extending through the semiconductor pattern to form a contact plug for connecting the memory impurity region and the lower transistor.

In other embodiments, the memory cell gate electrode may be formed by forming a floating gate electrode, a gate insulating layer, and a control gate electrode, which may be sequentially stacked on the semiconductor pattern having the memory gate insulating layer.

According to some embodiments of the present invention, an integrated circuit memory device on a multi-layer substrate may include first and second selection transistors, a first plurality of serially connected memory cell transistors on a first substrate layer, and a second plurality of serially connected memory cell transistors on a second substrate layer different from the first substrate layer. The first plurality of serially connected memory cell transistors may be serially connected between the first and second selection transistors. The second plurality of serially connected memory cell transistors may also be serially connected between the first and second selection transistors.

In some embodiments, the device may further include an interconnection structure. The first and second pluralities of serially connected memory cell transistors may be serially connected between the first and second selection transistors by the interconnection structure. The interconnection structure may also electrically connect the first and second pluralities of serially connected memory cell transistors in parallel.

In other embodiments, the first and second selection transistors may be on a third substrate layer different from the first and/or second substrate layers. The device may further include a first insulating layer between the first and second substrate layers, and a second insulating layer between the second and third substrate layers. The interconnection structure may extend through the first and second insulating layers to electrically connect the first and second pluralities of serially connected memory cell transistors and the first and second selection transistors.

In some embodiments, the interconnection structure may include a first contact plug and a second contact plug. The first contact plug may electrically connect a source/drain region of the first selection transistor to a source/drain region of a first one of the first plurality of serially connected memory cell transistors and to a source/drain region of a first one of the second plurality of serially connected memory cell transistors. The second contact plug may electrically connect a source/drain region of the second selection transistor to a source/drain region of a last one of the first plurality of serially connected memory cell transistors and to a source/drain region of a last one of the second plurality of serially connected memory cell transistors.

In other embodiments, the first and second conductive plugs may extend from the third substrate layer through the first and second substrate layers to respectively electrically connect the source/drain regions of the first and last ones of the first and second pluralities of serially connected memory cell transistors to the source/drain regions of the first and second selection transistors. The source/drain regions of the first and last ones of the first and second pluralities of serially connected memory cell transistors may respectively extend through the first and second substrate layers to respectively electrically contact the first and second conductive plugs at sidewalls thereof.

In some embodiments, the first and second conductive plugs may respectively include first and second portions. The first portions may extend from the third substrate layer adjacent the first and second substrate layers, and the second portions may extend on the first and second substrate layers to respectively electrically connect the source/drain regions of the first and last ones of the first and second pluralities of serially connected memory cell transistors to the source/drain regions of the first and second selection transistors.

In other embodiments, the device may further include a third plurality of serially connected memory cell transistors on the first substrate layer and extending substantially parallel to the first plurality of serially connected memory cell transistors. An isolation layer may be formed in the first substrate layer between the first and third pluralities of serially connected memory cell transistors.

In some embodiments, the isolation layer may extend partially into the first substrate layer to separate the first and third pluralities of serially connected memory cells. The first and third pluralities of serially connected memory cells may be erased by applying an erase voltage to the first substrate layer.

In other embodiments, the isolation layer may extend through the first substrate layer to separate the first substrate layer into at least two bar-shaped layers. Ones of the first and third pluralities of serially connected memory cells may be erased by applying an erase voltage to a word line connected thereto.

In some embodiments, the device may further include an epitaxial seed layer adjacent the first and second substrate layers. The first and/or second substrate layers may be epitaxially grown from the epitaxial seed layer and/or the multi-layer substrate.

According to further embodiments of the present invention, an integrated circuit memory device may include a multi-layer substrate, first and second selection transistors on a first layer of the substrate, and a plurality of serially connected memory cell transistors on a second layer of the substrate. The device may further include an insulating layer between the first and second layers of the substrate, and first and second interconnection plugs extending through the insulating layer from the first layer to the second layer. The first and second interconnection plugs may electrically connect the plurality of serially connected memory cell transistors in series between the first and second selection transistors.

In some embodiments, the insulating layer may be a first insulating layer, and the plurality of serially connected memory cell transistors may be a first plurality of serially connected memory cell transistors. The device may further include a second plurality of serially connected memory cell transistors on a third layer of the substrate, and a second insulating layer between the second and third layers of the substrate. The first and second interconnection plugs may further extend through the second insulating layer to electrically connect the first plurality of serially connected memory cell transistors in parallel with the second plurality of serially connected memory cell transistors.

According to still further embodiments of the present invention, a multi-layer integrated circuit memory device may include first and second selection transistors, a first plurality of serially connected memory cell transistors on a first substrate layer, and a second plurality of serially connected memory cell transistors on a second substrate layer. An interconnection structure may electrically connect the first plurality of memory cell transistors in parallel with the second plurality of memory cell transistors and in series between the first and second selection transistors.

In some embodiments, the device may further include a first plurality of word lines, a second plurality of word lines, and a bit line. The first plurality of word lines may be respectively electrically connected to the first plurality of serially connected memory cell transistors on the first substrate layer. The second plurality of word lines may be respectively electrically connected to the second plurality of serially connected memory cell transistors on the second substrate layer. The bit line may be electrically connected to one of the first and second selection transistors by the interconnection structure.

According to other embodiments of the present invention, a method of fabricating an integrated circuit memory device may include forming first and second selection transistors on a first substrate layer, forming a plurality of serially connected memory cell transistors on a second substrate layer, and forming an insulating layer between the first and second layers of the substrate. The method may further include forming first and second interconnection plugs extending through the insulating layer from the first substrate layer to the second substrate layer. The first and second interconnection plugs may electrically connect the plurality of serially connected memory cell transistors in series between the first and second selection transistors.

In some embodiments, the method may further include forming a second plurality of serially connected memory cell transistors on a third substrate layer, and forming a second insulating layer between the second and third substrate layers. The first and second interconnection plugs may be formed to extend through the second insulating layer to electrically connect the first plurality of serially connected memory cell transistors in parallel with the second plurality of serially connected memory cell transistors. The first and second pluralities of serially connected memory cell transistors may be formed using a same mask pattern.

In other embodiments, the first interconnection plug may be formed to extend from a source/drain region of the first selection transistor on the first substrate layer through the second and third substrate layers to electrically connect to a source/drain region of a first one of the first plurality of serially connected memory cell transistors and to a source/drain region of a first one of the second plurality of serially connected memory cell transistors. The second interconnection plug may be formed to extend from a source/drain region of the second selection transistor on the first substrate layer through the second and third substrate layers to electrically connect to a source/drain region of a last one of the first plurality of serially connected memory cell transistors and to a source/drain region of a last one of the second plurality of serially connected memory cell transistors.

In some embodiments, the first interconnection plug may include a first portion extending from a source/drain region of the first selection transistor on the first substrate layer adjacent the second and third substrate layers and second portions extending from the first portion onto the second and third substrate layers to electrically connect to a source/drain region of a first one of the first plurality of serially connected memory cell transistors and to a source/drain region of a first one of the second plurality of serially connected memory cell transistors. The second interconnection plug may include a first portion extending from a source/drain region of the second selection transistor on the first substrate layer adjacent the second and third substrate layers and second portions extending from the first portion onto the second and third substrate layers to electrically connect to a source/drain region of a last one of the first plurality of serially connected memory cell transistors and to a source/drain region of a last one of the second plurality of serially connected memory cell transistors.

In other embodiments, the method may further include forming an epitaxial seed layer on the first substrate layer. The second and/or third substrate layers may be epitaxially grown from the first substrate layer and/or the epitaxial seed layer.

### BRIEF DESCRIPTION OF THE DRAWINGS

FIG. 1 is a plan view illustrating semiconductor devices according to some embodiments of the present invention;

FIGS. 2A through 10A are cross-sectional views taken along line I-I′ of FIG. 1 illustrating methods of fabricating a semiconductor device according to some embodiments of the present invention;

FIGS. 2B through 10B are cross-sectional views taken along line II-II′ of FIG. 1 illustrating methods of fabricating a semiconductor device according to some embodiments of the present invention;

FIG. 11 is a plan view illustrating semiconductor devices according to further embodiments of the present invention;

FIGS. 12A through 16A are cross-sectional views taken along line I-I′ of FIG. 11 illustrating methods of fabricating a semiconductor device according to further embodiments of the present invention;

FIGS. 12B through 16B are cross-sectional views taken along line II-II′ of FIG. 11 illustrating methods of fabricating a semiconductor device according to further embodiment of the present invention;

FIG. 17 is a cross-sectional view illustrating a peripheral circuit region of a semiconductor device according to some embodiments of the present invention;

FIG. 18 is a table illustrating operations of NAND flash memory according to some embodiments of the present invention; and

FIG. 19 is a table illustrating operations of NAND flash memory according to further embodiments of the present invention.

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

Semiconductor devices may include electronic elements integrated on semiconductor substrates. The semiconductor substrates may be formed of materials having particular characteristics, such as rapid conductance variation depending on an applied voltage. For example, some semiconductor devices may be formed from silicon wafers. Accordingly, in some embodiments of the present invention, the semiconductor substrate may be a silicon wafer or a germanium wafer.

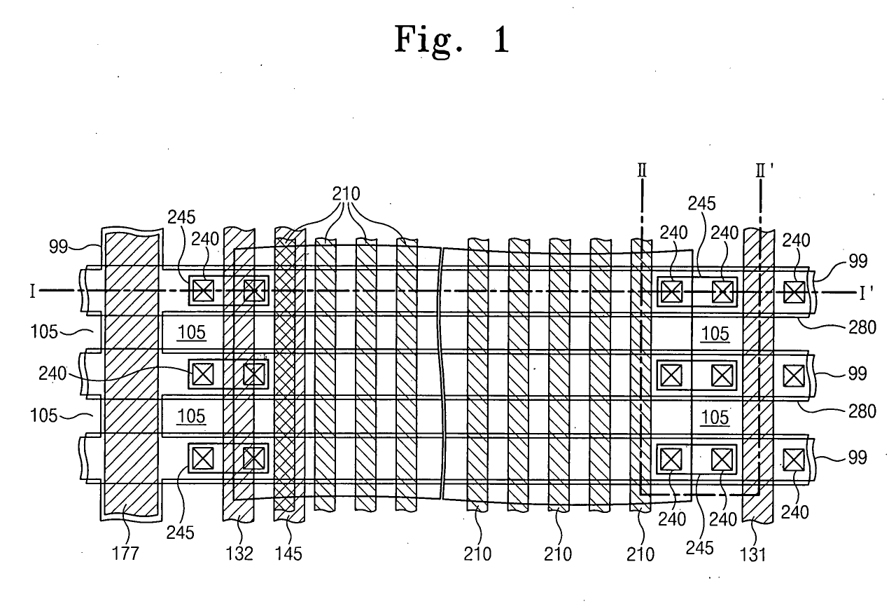

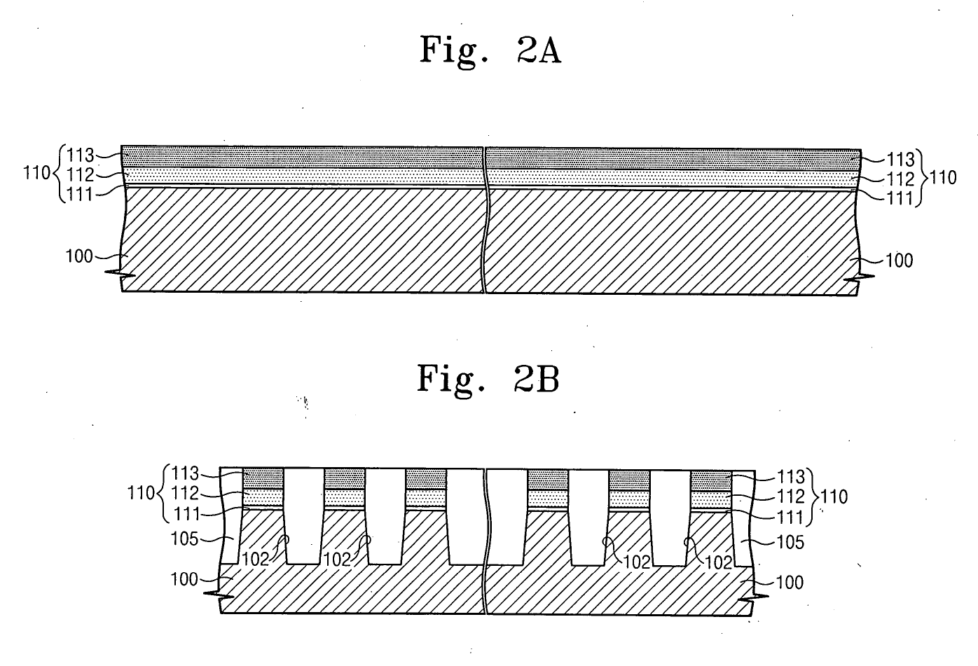

In some semiconductor devices, transistors may be formed and arranged in two-dimensions (i.e., along a length and width of a single layer) on semiconductor substrates. As such, higher integration of these semiconductor devices may be limited due to the two-dimensional arrangement of these transistors. However, as shown in FIG. 1, because semiconductor devices having multi-layered semiconductor patterns may include transistors arranged in three-dimensions, it may be possible to overcome the limits on integration which may be imposed by two-dimensional arrangements.

FIG. 1 is a plan view illustrating a semiconductor device according to some embodiments of the present invention. FIGS. 2A through 10A are cross-sectional views taken along line I-I′ of FIG. 1, illustrating methods of fabricating a semiconductor device according to some embodiments of the present invention. FIGS. 2B through 10B are cross-sectional views taken along line II-II′ of FIG. 1, illustrating methods of fabricating a semiconductor device according to some embodiments of the present invention.

Referring to FIGS. 1, 2A, and 2B, device isolation patterns 105 defining active regions 99 at predetermined regions of a semiconductor substrate 100 are formed. The device isolation patterns 105 may be formed by forming trench mask patterns 110 defining the active regions 99 on the semiconductor substrate 100, and anisotropically etching the semiconductor substrate 100 using the trench mask patterns as an etch mask to form trenches 102. The trench mask pattern 110 may include a pad oxide layer 111, a trench lower mask layer 112, and a trench upper mask layer 113, which are sequentially stacked. For example, the trench lower mask layer 112 may be polysilicon, and the trench upper mask layer 113 may be silicon nitride.

After forming the trenches 102, a predetermined ion implantation process for enhancing insulation characteristic is performed. A thermal oxide layer is formed on an inner sidewall of the trench 102, for example to have a thickness of approximately 50 Å. After forming a device isolation layer filling the trenches 102, the device isolation layer is planarized until the trench mask patterns 110 are exposed, thereby forming the device isolation patterns 105.

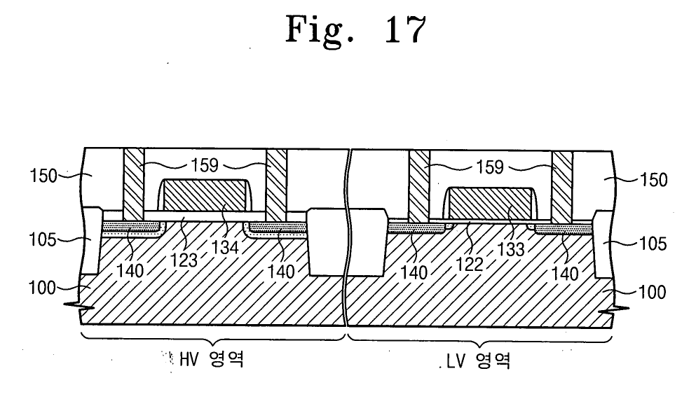

The device isolation patterns 105 may be formed in a cell array region as well as a peripheral circuit region in the manner described above. Devices configured to operate the transistors formed in the cell array region may be formed in the peripheral circuit region (see FIG. 17).

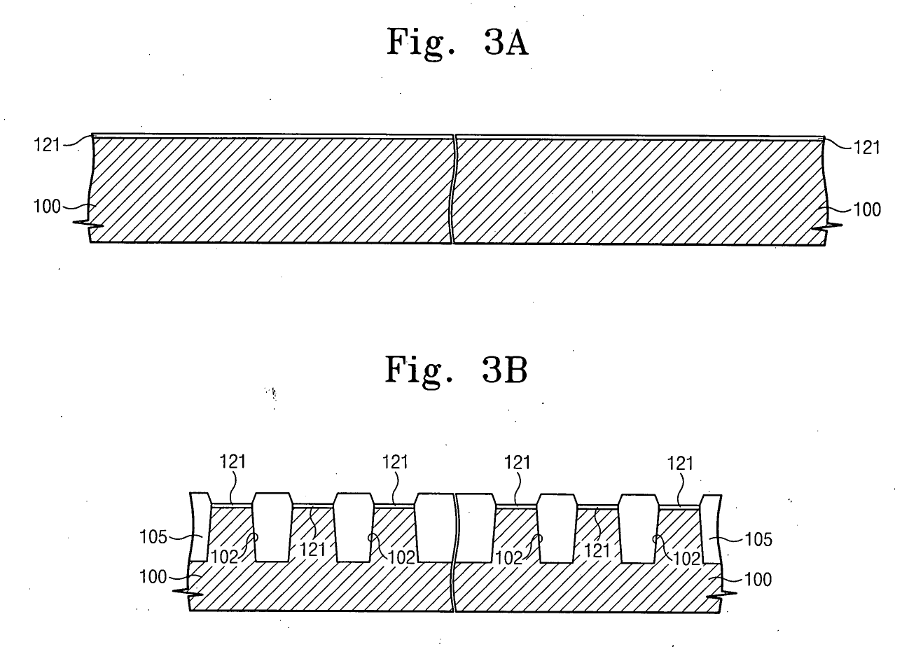

Referring to FIGS. 1, 3A, and 3B, the trench upper mask layer 113, the trench lower mask layer 112, and the pad oxide layer 111 are sequentially removed using a wet etching process to expose an upper surface of the active region 99. Subsequently, first, second, and third gate insulating layers 121, 122, and 123 are formed on the upper surface of the exposed active region 99. In some embodiments of the present invention, the first gate insulating layer 121 may be a silicon oxide layer having a thickness of approximately 70 Å in the cell array region. The second gate insulating layer 122 may be a silicon oxide layer having a thickness of approximately 70 Å in the peripheral circuit region (see FIG. 17). The third gate insulating layer 123 may be a silicon oxide layer having a thickness of approximately 350 Å in the peripheral circuit region (see FIG. 17).

The second gate insulating layer 122 is formed in the low voltage transistor region (LV region), and the third gate insulating layer 123 is formed in the high voltage transistor region (HV region). The second gate insulating layer 122 may be formed in the same fabrication step as the first gate insulating layer 121. Moreover, the third gate insulating layer having a thickness of 400 Å may be formed before forming the first gate insulating layer 121. Then the third gate insulating layer 123 having a thickness of 350 Å may be formed by removing the pad oxide layer 111 and forming the first gate insulating layer 121. Various first, second, and third gate insulating layers 121, 122, and 123 can be formed depending on a kind of material, thickness, and/or formation method.

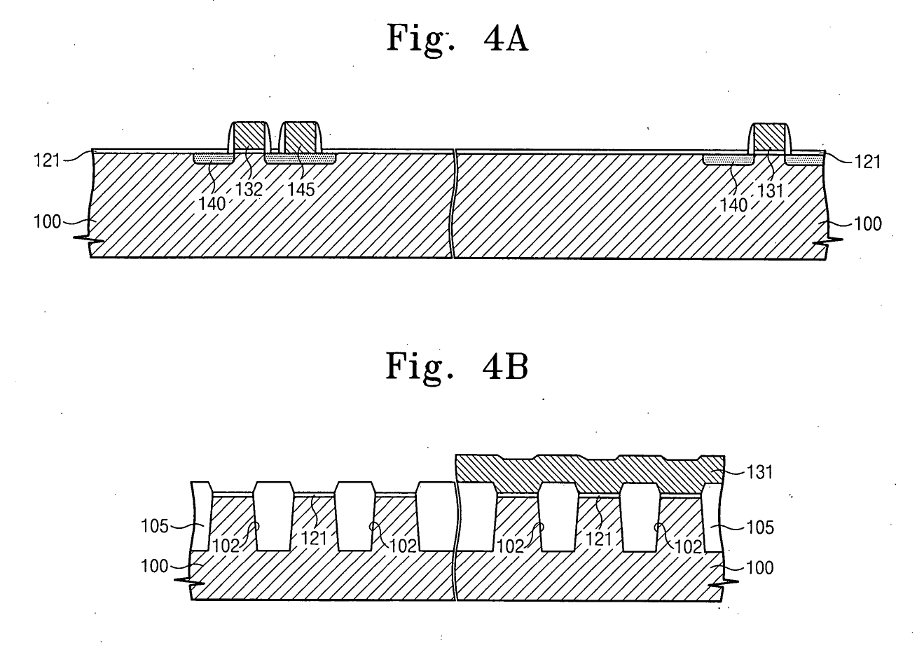

Referring to FIGS. 1, 4A, and 4B, a gate conductive layer is formed on the gate insulating layers 121, 122, and 123. The gate conductive layer may have a tungsten-polycide structure that includes N-type polysilicon and tungsten silicide. Then, the gate conductive layer is patterned to form a string select line (SSL) 131, a ground select line (GSL) 132, a low voltage gate 133, and a high voltage gate 134. The string select line 131 and the ground select line 132 are formed to cross over the active regions 99 in the cell array region. The low voltage gate 133 and the high voltage gate 134 are formed in the low voltage transistor region (LV region) and the high voltage transistor region (HV region), respectively, of the peripheral circuit region.

Impurity regions (i.e., source/drain regions) 140 are formed in the semiconductor substrate 100 adjacent the string select line 131, the ground select line 132, the low voltage gate 133, and the high voltage gate 134. The impurity regions 140 may be formed so as to have different conductivity-type, concentration, and/or junction profile with respect to their positions. After forming the impurity regions 140, a common source line 145 electrically connected to the impurity region 140 formed at one side of the ground select line 132 may be further formed. Moreover, impurity regions formed at both sides of the low voltage gate 133 and the high voltage gate 134, as shown in FIG. 17, may have a Lightly Doped Drain (LDD) junction structure and a Double Doped Drain (DDD) structure, respectively. Accordingly, a low voltage transistor is formed in the low voltage transistor region (LV region), and a high voltage transistor is formed in the high voltage transistor (HV region).

A spacer may be formed on sidewalls of the string select line 131, the ground select line 132, the low voltage gate 133, and the high voltage gate 134. The spacer may be used as an ion implantation mask in forming the impurity region 140.

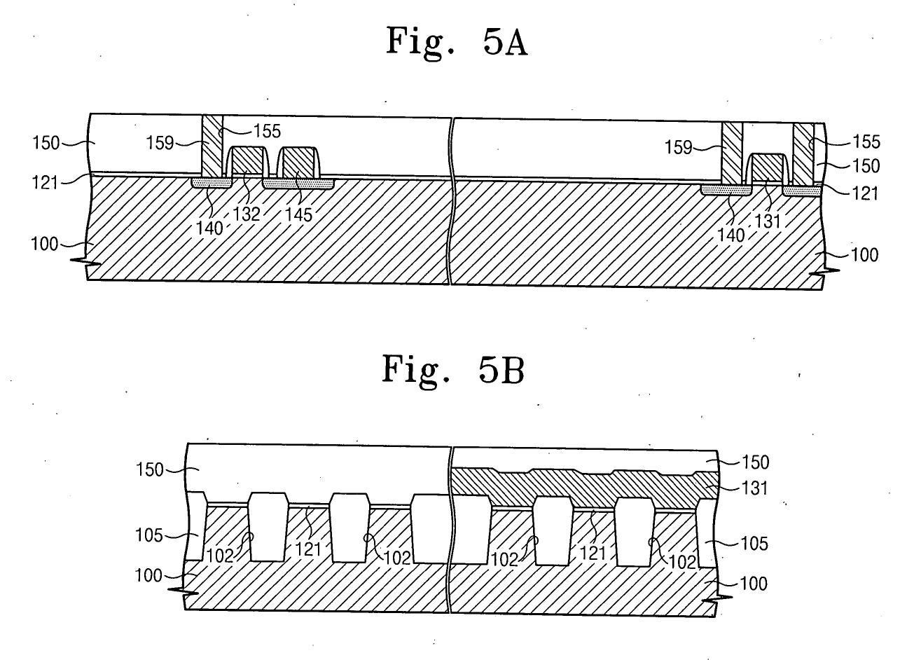

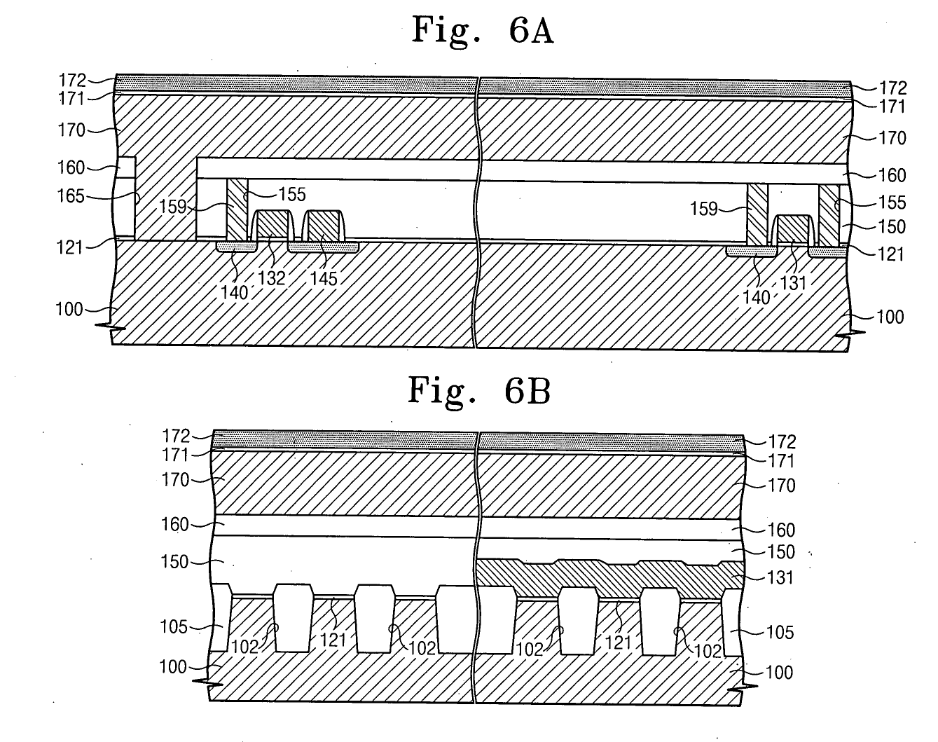

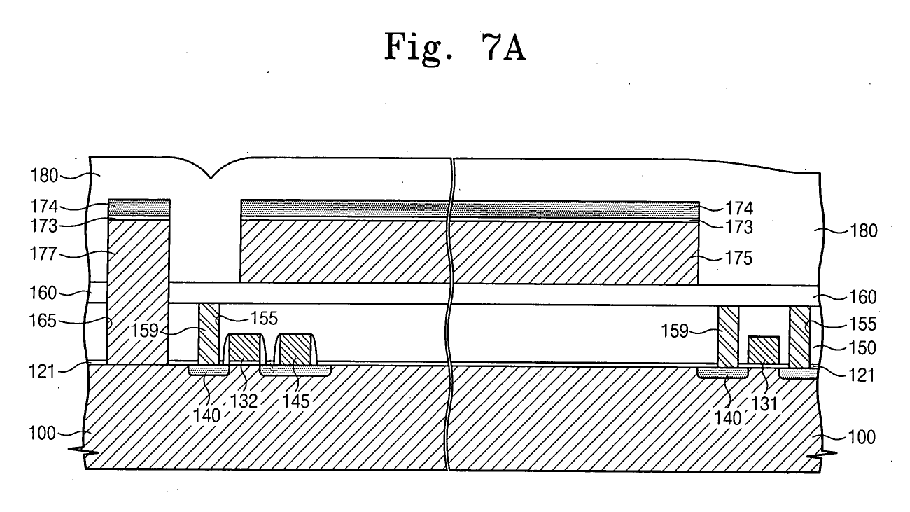

Referring to FIGS. 1, 5A, and 5B, a first insulating layer 150 is formed on the semiconductor substrate 100 including the string selection line 132, the ground select line 132, the low voltage gate 133, and the high voltage gate 134. The first insulating layer 150 may be formed of a silicon oxide layer such as High Density Plasma (HDP) oxide layer, BPSG, and/or a plasma enhanced tetraethylorthosilicate (PE-TEOS) layer. The first insulating layer 150 may be formed by depositing the first insulating layer to approximately 8000 Å thickness, and planarizing the first insulating layer, for example, by Chemical Mechanical Polishing (CMP).

Subsequently, the first insulating layer 150 is patterned to form openings 155 exposing predetermined regions of the semiconductor substrate 100. More particularly, the first openings 155 expose predetermined regions of the impurity regions 140, adjacent the string select line 131, ground select line 132, low voltage gate 133, and high voltage gate 134. Furthermore, the first openings 155 may expose a pickup region formed at a predetermined region of the semiconductor substrate 100 in order to apply a voltage to the semiconductor substrate 100.

First contact plugs 159 filling the first openings 155 are formed. The first contact plugs 159 may be formed by forming a first conductive layer filling the first openings 155, and planarizing the first conductive layer until an upper surface of the first insulating layer is exposed. The planarization of the first conductive layer may be performed, for example, using a chemical mechanical polishing (CMP) process and/or an etch-back process. The first conductive layer may be formed of polysilicon, tungsten, titanium, and/or titanium nitride. Where the first conductive layer is polysilicon, the first conductive layer may further include N-type pr P-type impurities according to the conductivity of an impurity region 140 connected thereto.

Referring to FIGS. 1, 6A, and 6B, a second insulating layer 160 is formed on the structure including the first contact plugs 159. Then, the second insulating layer 160 and the first insulating layer 150 are patterned to form a second opening 165 exposing a predetermined region of the semiconductor substrate 100. The second insulating layer 160 may be a silicon oxide layer (for example, a high density plasma oxide layer having 1000 Å thickness) or a low-k dielectric layer. The second opening 165 may be formed at one side of the string select line 131 and/or the ground select line 132 and may be perpendicular to the device isolation layer 105. In some embodiments of the present invention, the second opening 165 may be formed between common source lines 145 and may extend parallel with the ground select line 132 and/or the common source line 145.

A selective epitaxial growth process is performed to form a semiconductor layer 170 filling the second opening 165 on the second insulating layer 160. In the selective epitaxial growth process, a silicon layer having a single crystalline structure may be grown from exposed regions of the semiconductor substrate 100. For example, the single crystalline silicon layer may be grown at a temperature of approximately 800° C. using a gas such as Dichlorosilane (DSC) and/or hydrochloric acid (HCl). In order to stabilize the grown single crystalline silicon layer, a predetermined thermal process may also be further performed. The semiconductor layer 170 is grown thicker than the sum of the thickness of the first and second insulating layers 150 and 160 so as to extend cover beyond the second opening 165 and upper surfaces of the second insulating layer 160. Then, a planarizing etching process such as CMP is performed to planarize an upper surface of the semiconductor layer 170. To control the thickness of the semiconductor layer 170 remaining on the second interlayer insulating layer 160, the etching time etching the semiconductor layer 170 may be controlled.

Then, a lower mask layer 171 and an upper mask layer 172 are sequentially formed on the semiconductor layer 170. The lower mask layer 171 may be a silicon oxide layer having a thickness of about 100 Å, and the upper mask layer 172 may be a silicon nitride layer having a thickness of about 1000 Å.

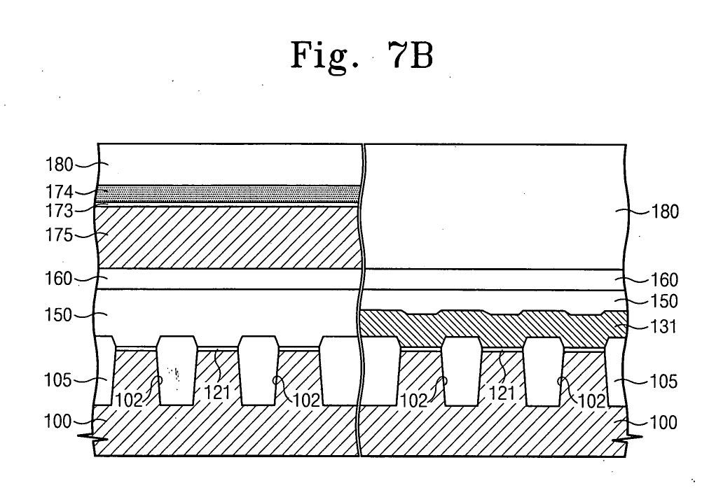

Referring to FIGS. 1, 7A, and 7B, the semiconductor layer 170 is patterned to form semiconductor patterns 175 and epitaxial seed patterns 177. In the patterning process, the lower mask layer 171 and the upper mask layer 172 are sequentially patterned to form a lower mask pattern 173 and an upper mask pattern 174 that are sequentially stacked. The semiconductor layer 170 is then anisotropically etched using the upper and lower mask patterns 173 and 174 as an etch mask.

In accordance with some embodiments of the present invention, the semiconductor patterns 175 are formed between the string select line 131 and the ground select line 132. Accordingly, portions of the semiconductor layer 170 on the string select line 131 are removed. Also, the epitaxial seed pattern 177 is formed at a region where the second opening 165 is formed.

Since the semiconductor layer 170 is formed using a selective epitaxial growth process, boundaries with a discontinuous single crystalline structure may be formed. However, since the second opening 165 and the epitaxial seed pattern 177 are formed between adjacent ground select lines 132, the discontinuous boundaries are formed between two adjacent epitaxial seed patterns 177. In addition, because portions of the semiconductor layer 170 located on the string select transistors are removed by the patterning process, the discontinuous boundaries are not included in the semiconductor patterns 175. Thus, the semiconductor patterns 175 may be formed of single crystalline silicon without (or with reduced) discontinuous boundaries. As a result, transistors employing semiconductor characteristic of single crystalline silicon may be formed using the semiconductor patterns 175.

Still referring to FIGS. 1, 7A, and 7B, a third insulating layer 180 is formed covering the semiconductor patterns 175 and the epitaxial seed patterns 177. The third insulating layer 180 may be a high density plasma (HDP) oxide layer, which may be formed to a greater thickness than the semiconductor patterns 175.

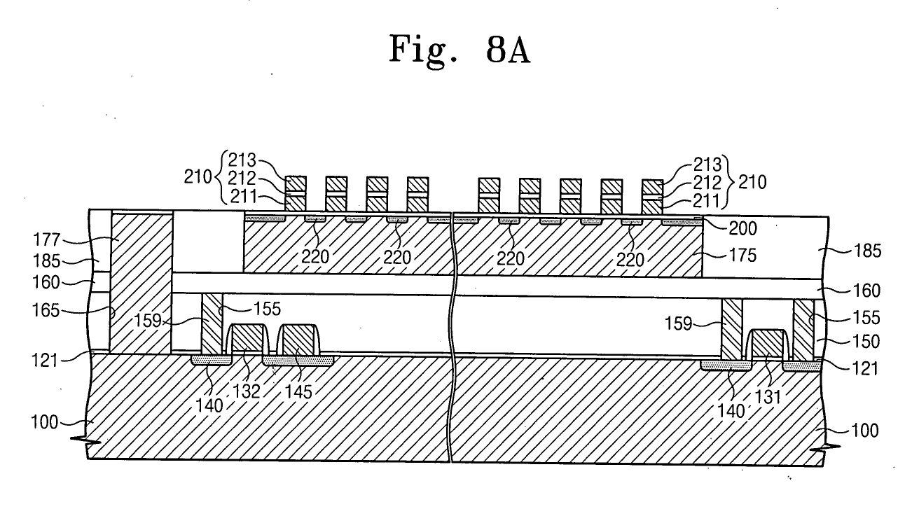

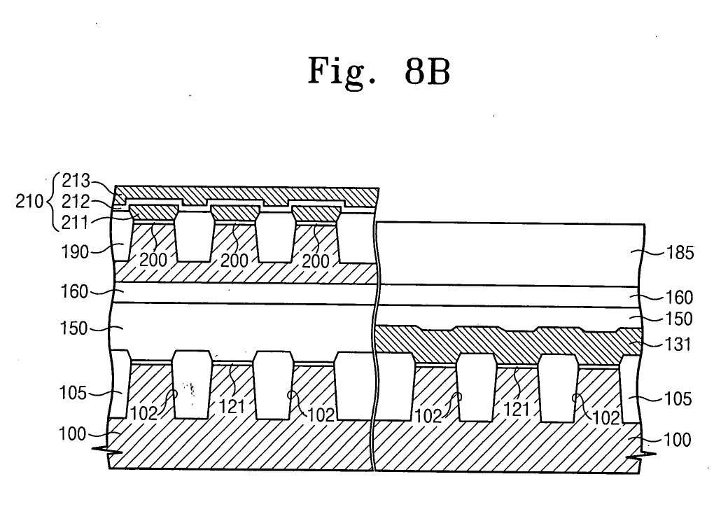

Referring to FIGS. 1, 8A, and 8B, the third interlayer insulating layer 180 is planarized until the upper mask pattern 174 is exposed to form third insulating layers 185 arranged between the semiconductor patterns 175 and the epitaxial seed patterns 177. For example, the planarization process may be performed using CMP. Subsequently, the exposed upper and lower mask patterns 174 and 173 are removed using a wet etching process to expose upper surfaces of the semiconductor patterns 175.

A memory mask pattern defining a memory active region is formed on an upper portion of the exposed semiconductor patterns 175. The memory mask pattern may include a lower memory mask layer and an upper memory mask layer, which are sequentially stacked. The lower memory mask layer may be a silicon oxide layer having a thickness of approximately 50 Å, and the upper memory mask layer may be a silicon nitride layer having a thickness of approximately 1500 Å. Next, the semiconductor patterns 175 are anisotropically etched using the memory mask pattern as an etch mask to form a memory trench having a predetermined depth. To enhance insulation characteristics between the memory active regions, an ion implantation process for implanting boron (B) into the memory trench is performed.

Then, a thermal oxide layer is grown to a thickness of about 50 Å on inner sidewalls of the memory trench. A high density plasma (HDP) oxide layer is deposited to a thickness of about 6000 Å on a resultant structure where the thermal oxide layer is formed. The deposited HDP oxide layer is planarized to expose an upper surface of the memory mask pattern, thereby forming memory device isolation patterns 190 for electrically isolating the memory active regions. After that, the exposed memory mask pattern is removed using a wet etching process to expose an upper surface of the memory active region.

A memory gate insulating layer 200 is formed on the memory active region. The memory gate insulating layer 200 may be a silicon oxide layer having a thickness of about 70 Å, which may be formed by thermally oxidizing the upper surface of the exposed active region. A floating gate conductive layer is formed on the gate insulating layer 200. The floating gate conductive layer may be formed of N-type polysilicon having a thickness of approximately 800 Å. Next, the floating gate conductive layer is patterned to form a floating gate pattern. The floating gate pattern is formed on an upper portion of the memory active regions and then patterned so as to expose upper surfaces of the memory device isolation patterns 190. Accordingly, the floating gate pattern may be perpendicular to the string select line 131 and the ground select line 132.

In some embodiments, in order to overcome the limitations of conventional photolithography processes, the floating gate pattern may be formed by forming a sacrificial pattern on the floating gate conductive layer, forming a spacer around the sacrificial pattern, removing the sacrificial pattern, and patterning the floating gate conductive layer using the spacer as a mask.

Then, a gate insulating layer and a control gate conductive layer are formed on the floating gate pattern. The gate insulating layer may include a silicon oxide layer, a silicon nitride layer, and a silicon oxide layer, which are sequentially stacked. In addition, the control gate conductive layer may include a N-type polysilicon layer and a tungsten silicide layer, which are sequentially stacked. The control gate conductive layer, the gate insulating layer, and the floating gate pattern are sequentially patterned to form word lines 210. The word lines 210 may include a floating gate electrode 211, an intergate insulating pattern 212, and a control gate electrode 213, which are sequentially stacked. The floating gate 211 is electrically isolated for use as a charge storage layer. Accordingly, the word lines 210 have a flash memory gate structure.

The word lines 210 are patterned to be parallel with the string select line 131 and the ground select line 132. Accordingly, the word lines 210 perpendicularly cross the memory active region. According to some embodiments of the present invention, memory cell transistors are formed at intersections of the word lines 210 and the memory active region. An ion implantation process is performed using the word lines 210 as a mask to form memory impurity regions 220 (i.e., source/drain regions for the memory cell transistors) in the semiconductor patterns 175 between the word lines 210.

In addition, the memory cell transistors may also be formed at the semiconductor substrate 100. That is, the memory cell transistors may be formed at an empty region between the string select line 131 and the ground select line 132. Also, transistors having another function and/or electronic elements (such as a resistors) may be formed in the empty region.

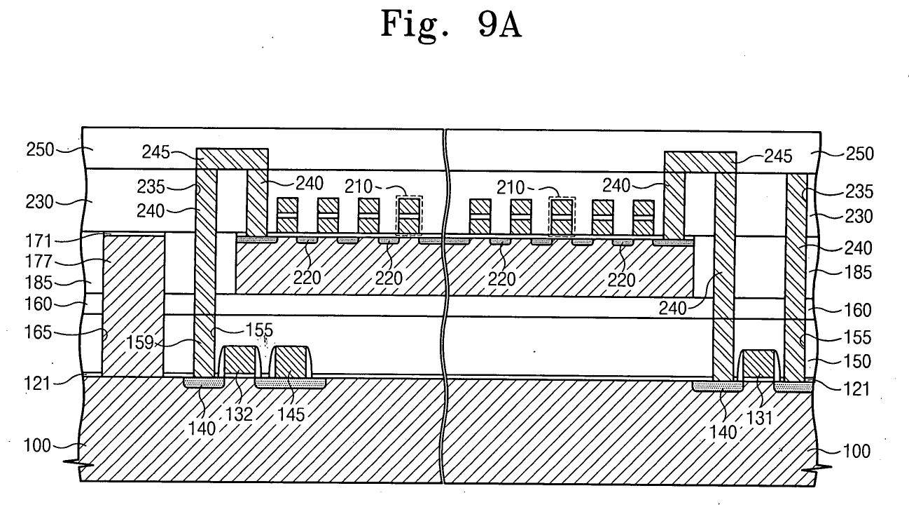

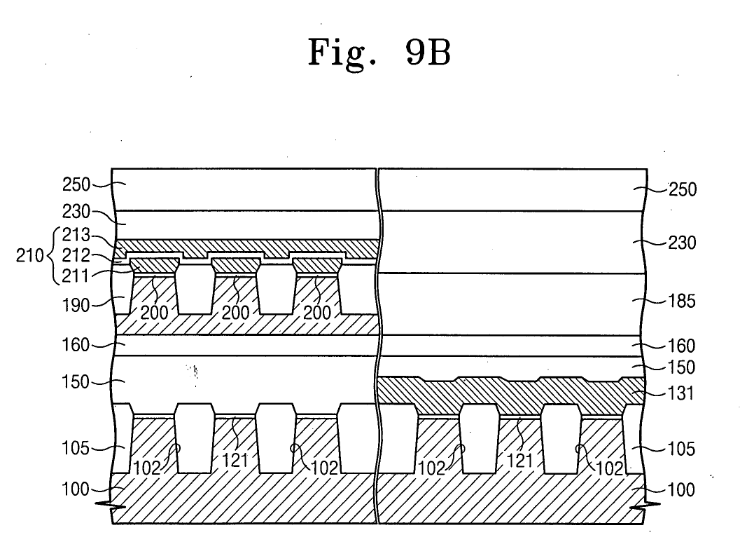

Referring to now FIGS. 1, 9A, and 9B, a fourth insulating layer 230 is formed on the memory impurity regions 220. The fourth insulating layer 230 may be formed of a silicon oxide layer such as high density plasma oxide (HDP), borophosphosilicate (BPSG), and/or plasma-enhanced tetraethyl orthosilicate (PE-TEOS). The fourth insulating layer 230 may be formed by depositing the fourth insulating layer to a thickness of approximately 8000 Å, and planarizing the fourth insulating layer by CMP. Subsequently, the fourth insulating layer 230 is patterned to form second openings 235 exposing the first contact plugs 159. Furthermore, the second openings 235 also expose memory impurity regions 220 formed at both ends of the semiconductor patterns 175.

Second contact plugs 240 filling the second openings 235 are formed. The second contact plugs 240 may be formed by forming a second conductive layer filling the second openings 235, and planarizing the second conductive layer until an upper surface of the fourth insulating layer 230 is exposed. The planarization process may be performed, for example, using an etch-back process and/or CMP. The second conductive layer may be formed of polysilicon, tungsten, aluminum, and/or titanium nitride. Where polysilicon is used, the second conductive layer may include N-type or P-type impurities according the conductivity of an impurity region connected thereto.

Interconnections 245 for connecting the second contact plugs 240 are then formed, to provide a lower memory structure 1000. In forming the interconnections 245, the second contact plugs 240 may be formed using a damascene process. As such, the first contact plugs 159, the second contact plugs 240, and the interconnections 245 may form an interconnection structure electrically connecting the memory cell transistors on semiconductor pattern 175 in series between the string select transistor and the ground select transistor.

A fifth insulating layer 250 is formed on a surface of the substrate 100 including the interconnections 245. The fifth insulating layer 250 may be a high density plasma oxide having a thickness of about 1000 Å.

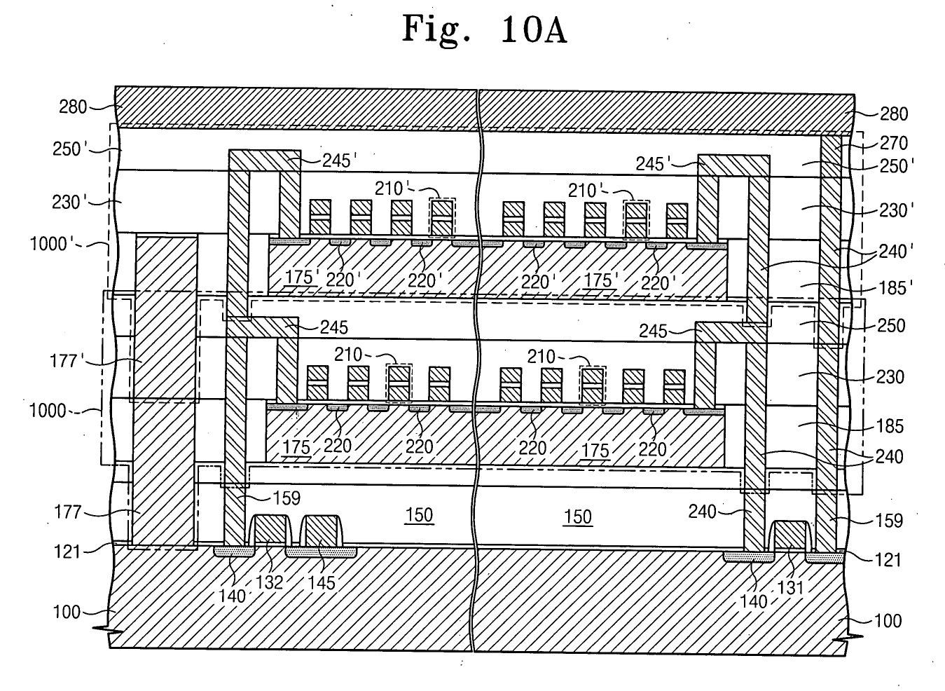

Referring to FIGS. 1, 10A, and 10B, after forming the fifth insulating layer 250, an upper memory structure 1000′ is formed. In forming the upper memory structure 1000′, the process for forming the lower memory structure 1000 may be repeated. This process may include steps, for example, from forming the second openings 165 to forming the fifth insulating layer, as described above with reference to FIGS. 6A and 6B to 9A and 9B. As a result, the upper and lower memory structures 1000′ and 1000 may have a similar structure. As such, the upper memory structure 1000′ may be formed using the same photomask used for forming the lower memory structure 1000, so that the cost of fabricating an additional photomask may not be required.

In accordance with other embodiments of the present invention, the steps for forming the upper memory structure 1000′ may be performed repeatedly. As such, polysilicon multi-layered semiconductor patterns 175 and 175′ and memory cell transistors thereon may be formed. The memory cell transistors may be formed in a multi-layered memory cell transistor structure, thereby minimizing occupied area. More particularly, serially connected memory cell transistors on pattern/layer 175 may be connected in parallel to serially connected memory cell transistors on pattern/layer 175′, and may be connected in series between selection transistors. Accordingly, integration density in semiconductor devices may be increased.

Still referring to FIGS. 1, 10A, and 10B, bit lines 280 crossing over the word lines 210 and 210′ are formed on an upper portion of the upper memory structure 1000′. The bit lines 280 are electrically connected through the second contact plugs 240 and 240′ and the first contact plugs 159 to an impurity region 140 formed at one side of the string selection line 131. An upper plug 270 extends through the fifth insulating layer 250′ of the upper memory structure 1000′ to connect the bit line 280 and the second contact plugs 240′. A protective layer is further formed on the bit lines 280.

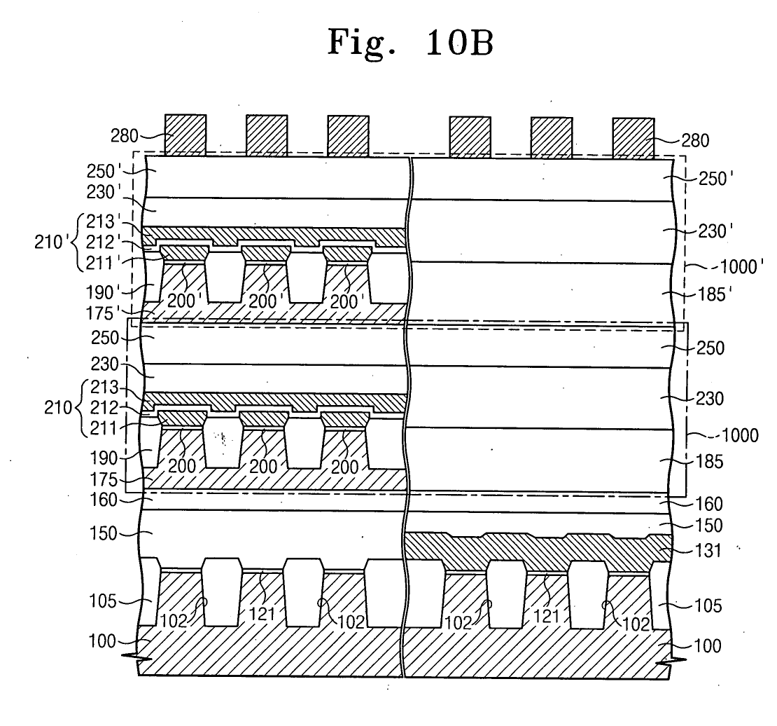

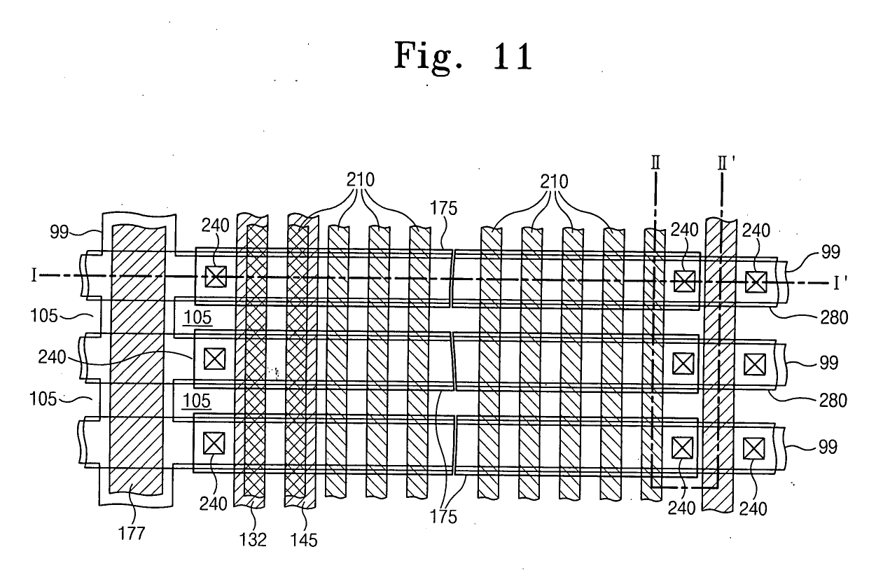

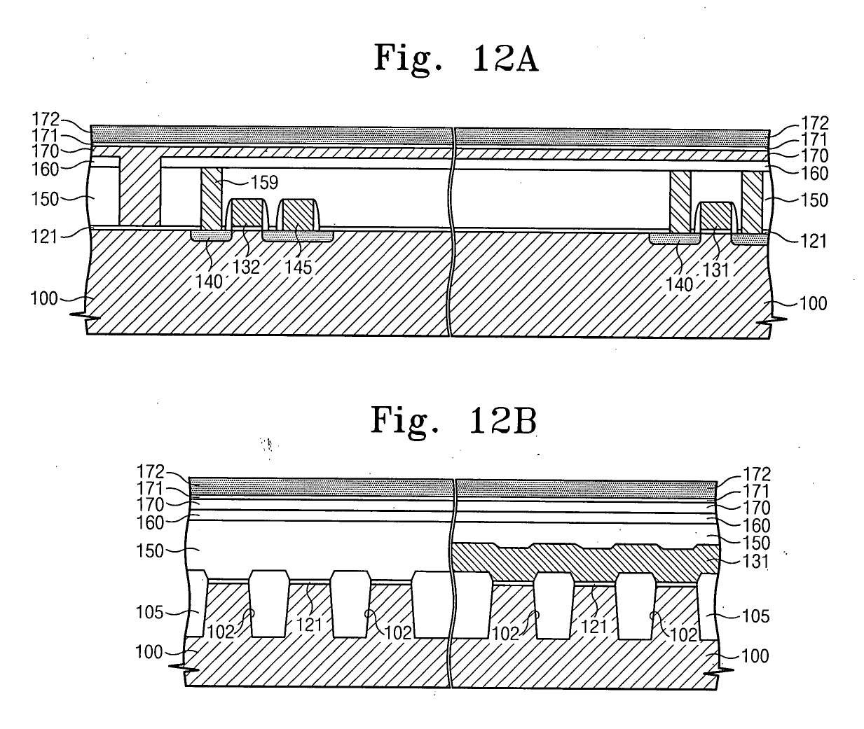

FIG. 11 is a plan view illustrating a semiconductor device according to further embodiments of the present invention. FIGS. 12A through 16A and 12B through 16B are cross-sectional views taken along lines I-I′ and II-II′ of FIG. 11 illustrating a method of fabricating a semiconductor device according to further embodiments of the present invention. In these further embodiments, the thickness of semiconductor patterns 175 and arrangement of second contact plugs 240 may differ from the embodiments described above. In other words, further embodiments of the present invention may be similar to the above-described embodiments except for the thicknesses and arrangements mentioned above. Thus, similar description will be omitted hereinafter for the sake of brevity.

Referring now to FIGS. 11, 12A, and 12B, a second insulating layer 160 is formed on the first insulating layer 150 and the first contact plugs 159, as illustrated in FIGS. 5A and 5B. The process for forming the first contact plugs 159 may be the same as in the embodiments mentioned above. A second opening 165 is then formed. The second opening may extend through the second insulating layer 160 and the first insulating layer 150 to expose a predetermined region of the semiconductor substrate 100. Then, a semiconductor layer 170 is formed. The semiconductor layer fills the second opening 165 and is formed on the second insulating layer 160. As described above, the semiconductor layer 170 may be formed using a selective epitaxial growth process. To stabilize the grown single crystalline silicon layer, a predetermined thermal process may further be performed after the selective epitaxial growth process. A lower mask layer 171 and an upper mask layer 172 are sequentially formed on the semiconductor layer 170.

In some embodiments, the semiconductor layer 170 may be grown to a thickness greater than the combined thickness of the first and second insulating layers 150 and 160 so as to cover an upper surface of the second insulating layer 160. Then, a planarization process such as CMP may be performed to planarize an upper surface of the semiconductor layer 170. The thickness of the semiconductor layer 170 may be about 500 Å to about 1500 Å.

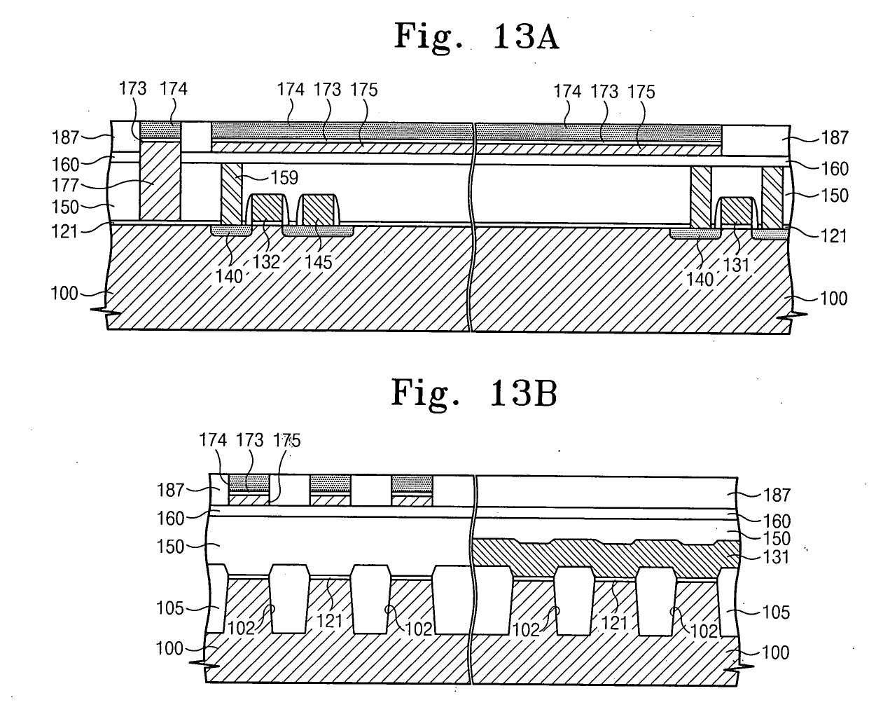

Referring now to FIGS. 11, 13A, and 13B, the semiconductor layer 170 is patterned to form a plurality of semiconductor patterns 175 and epitaxial seed patterns 177. The patterning process may include patterning the lower mask layer 171 and the upper mask layer 172 to form a lower mask pattern 173 and an upper mask pattern 174 which are sequentially stacked, and anisotropically etching the semiconductor layer using the lower and upper mask patterns 173 and 174 as an etch mask.

The semiconductor patterns 175 are patterned to extend perpendicular to the string select line 131 and the ground select line 132. For this, the lower and upper mask patterns 173 and 174 (used as etch masks) are also patterned to be perpendicular to the string select line 131 and the ground select line 132. Accordingly, the semiconductor patterns 175 may be bar-shaped, and may extend perpendicular to word lines. In contrast, the semiconductor patterns 175 of the embodiments described above with reference to FIG. 1 may be plate-shaped.

Subsequently, a third insulating layer is formed covering the semiconductor patterns 175 and the epitaxial seed patterns 177. Then, the third insulating layer is planarized until the upper mask pattern 174 is exposed. Accordingly, insulating patterns 187 between the semiconductor patterns 175 and the epitaxial seed patterns 177 are formed. The planarization process may be performed using CMP.

As the insulating patterns 187 are formed between the semiconductor patterns 175, the insulating patterns 187 may be used as a device isolation layer for electrically isolating transistors formed in the semiconductor patterns 175. Accordingly, in contrast with the embodiments described above, a process for forming an additional device isolation layer may not be performed.

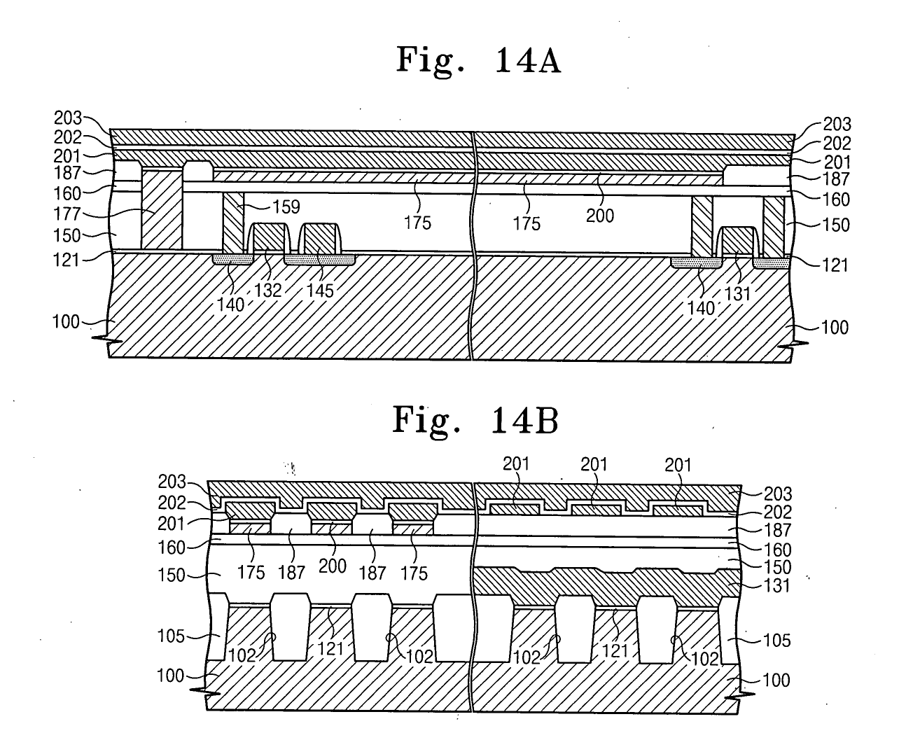

Referring to FIGS. 11, 14A, and 14B, the upper mask pattern 174 and the lower mask pattern 173 are removed using a wet etching process to expose upper surfaces of the semiconductor patterns 175. At this time, the insulating pattern 187 may be partially recessed. A memory gate insulating layer 200 and a floating gate conductive layer are sequentially formed on an upper surface of the exposed semiconductor patterns 175. The floating gate conductive layer is patterned to form floating gate patterns 201, which cover the upper surfaces of the semiconductor patterns 175 as well as expose upper surfaces of the insulating patterns 187. Accordingly, the floating gate pattern 201 is perpendicular to the string selection line 131 and the ground select line 132.

A gate insulating layer 202 and a control gate conductive layer 203 are formed on the floating gate patterns 201. The gate insulating layer 202 may include a silicon oxide layer, a silicon nitride layer, and a silicon oxide layer. Moreover, the control gate insulating layer may include a N-type polysilicon layer and a tungsten silicide layer, which are stacked sequentially.

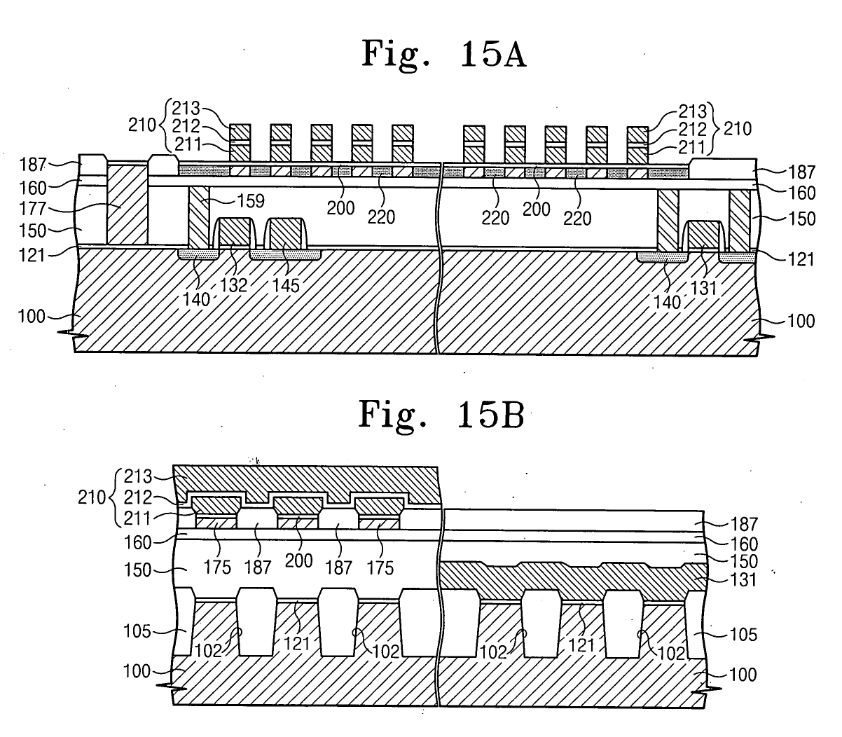

Referring now to FIGS. 11, 15A, and 15B, the control gate conductive layer 203, the gate insulating layer 202, and the floating gate insulating layer 201 are successively patterned to form word lines 210. The word lines, as shown in FIGS. 11, 15A, and 15B, include a floating gate electrode 211, an intergate insulating layer 212, and a control gate electrode 213, which are stacked sequentially. In addition, the word lines 210 are patterned to be parallel with the string select line 131 and the ground select line 132. Therefore, the word lines 210 cross the semiconductor patterns 175. In accordance with the present invention, memory cell transistors are formed at intersections of the word lines 210 and the semiconductor patterns 175. As such, an ion implantation process may be performed using the word lines 210 as a mask to form memory impurity regions 220 in the semiconductor patterns 175 between the word lines 210.

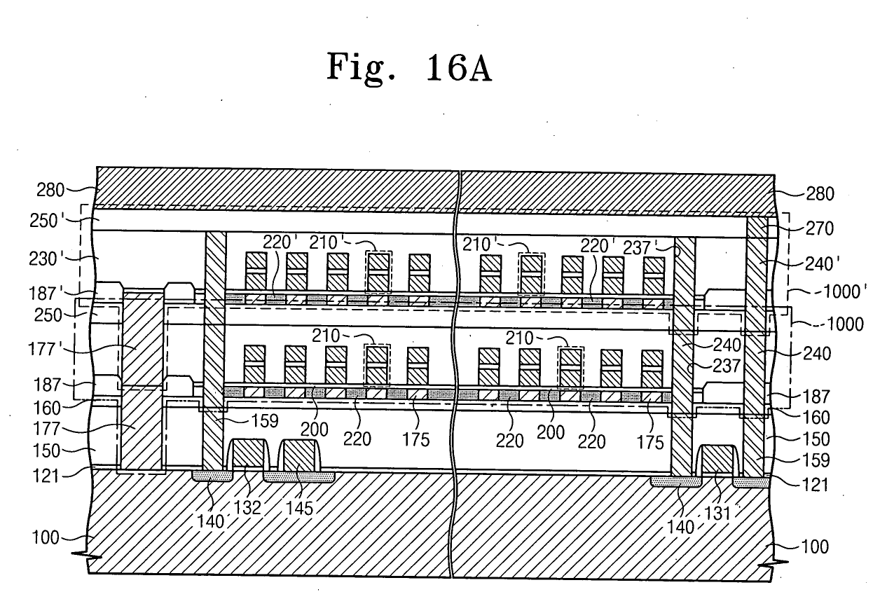

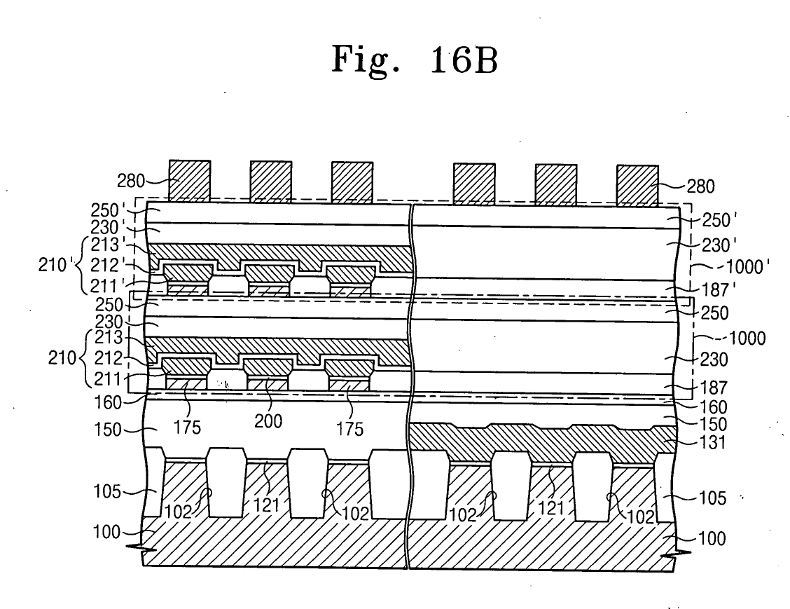

Referring now to FIGS. 11, 16A, and 16B, a fourth insulating layer 230 is formed on the substrate 100 including the memory impurity regions 220. Memory openings 237 are formed in the fourth insulating layer 230. The memory openings 237 extend through the fourth insulating layer 230, the semiconductor patterns 175, and the second insulating layer 160 to expose the first contact plugs 159.

Accordingly, the memory openings 237 extend through the memory impurity regions 220 and the semiconductor patterns 175. As such, the area of the semiconductor patterns 175 that may be available for storage cell transistors in a cell array may be increased as compared with the embodiments described above. As a result, even more highly integrated flash memory devices may be formed.

Still referring to FIGS. 11, 16A, and 16B, second contact plugs 240 filling the memory openings 237 are formed. As stated above, since the memory openings 237 extend through the memory impurity regions 220, the second contact plugs 240 are electrically connected to the memory impurity regions 220. As such, the first contact plugs 159 and the second contact plugs 240 may form an interconnection structure electrically connecting the memory cell transistors on semiconductor patterns 175 in series between the string select transistor and the ground select transistor. As a result, the interconnections 245 described above with reference to prior embodiments may not be required.

A fifth insulating layer 250 is then formed on the fourth insulating layer 248 including the second contact plugs 240. An upper memory structure 1000′ is formed on the fifth insulating layer 250. Bit lines 280 are formed crossing the word lines 210 and 210′ on an upper portion of the upper memory structure 1000′, and a protection layer is further formed on the bit lines 280. The upper memory structure 1000′ may be connected in parallel to the lower memory structure 1000 and in series between the selection transistors by the interconnection structure. Methods for forming the upper memory structure 1000′ may be similar to those described above.

As such, according to some embodiments of the present invention, semiconductor patterns and transistors formed thereon may have a multi-layered structure, where serially connected memory cell transistors on one layer are connected in parallel to serially connected memory cell transistors on another layer and connected in series between selection transistors.

Again referring to FIGS. 1, 10A, 10B, 16A, and 16B, a plurality of semiconductor patterns 175 are formed on a semiconductor substrate 100 having a cell array region and a peripheral circuit region. The semiconductor patterns 175 may be formed to different heights, to provide a multi-layered structure.

String select transistors and ground select transistors are formed in a cell array region of the semiconductor substrate 100. The string select transistor includes a string select line 131, a first gate insulating layer 121 between the string select lines 131 and the semiconductor substrate 100, and impurity regions 140 at both sides of the string select lines 131. The ground select transistor includes a ground select line 132 parallel with the string select line 131. The impurity region 140 is also formed on the semiconductor substrate 100 at both sides of the ground select line 132. In addition, sthe first gate insulating layer 121 is formed between the ground select line 132 and the semiconductor substrate 100.

Device isolation patterns 105 defining active regions 99 are formed in the semiconductor substrate 100. The device isolation patterns 105 are formed in a direction crossing the string select lines 131 in the cell array region. The device isolation patterns 105 may form a trench-type device isolation layer.

Memory cell transistors are formed in the semiconductor pattern 175. The memory cell transistors include a word line 210, a memory gate insulating layer 200, and memory impurity regions 210. The word lines 210 are parallel with the string select line 131 and the ground select line 132. The memory gate insulating layer 200 is between the word line 210 and the semiconductor pattern 175. The memory impurity regions 220 are formed in the semiconductor patterns 175 between the word lines 210. The word lines 210 may include a floating gate electrode 211, an intergate insulating pattern 212, and a control gate electrode 213, which are stacked sequentially. As such, the memory cell transistors may be NAND-type flash memory.

Memory device isolation patterns 190 defining a memory active region are formed in the semiconductor patterns 175. The memory device isolation patterns 190 are formed in a direction crossing the word lines 210 and may be bar-shaped.

In some embodiments of the present invention, the thickness of the semiconductor patterns 175 may be thinner than that of the semiconductor substrate 100. The thickness of the memory device isolation patterns 190 may be thinner than that of the semiconductor patterns 175 (see FIGS. 10A and 10B). As such, portions of the semiconductor patterns beneath the bit lines 280 may be connected. Accordingly, a voltage may be simultaneously applied to memory cell transistors formed in the semiconductor pattern 175, for example, to perform an erase operation. To apply the voltage, a pick-up region having a different conductivity than the memory impurity region may be formed in a predetermined region of the semiconductor patterns 175.

In further embodiments of the present invention, the thickness of the semiconductor patterns 175 may be thinner than that of the semiconductor substrate 100. The thickness of the memory device isolation patterns 190 may be greater than or equal to that of the semiconductor patterns 175 (see FIGS. 16A and 16B). As such, the memory device isolation patterns 190 may extend through the semiconductor patterns 175, separating portions of the semiconductor patterns 175 beneath the bit lines 280. Accordingly, the semiconductor patterns 175 may have a shape similar to the memory device isolation patterns 190. In other words, the semiconductor patterns 175 may form a plurality of parallel bar-shaped patterns that extend perpendicular to the word lines 210. Furthermore, the thickness of the memory impurity region 220 may be similar to that of the semiconductor pattern 175 and the memory device isolation layer 190. As such, it may be difficult for a voltage to be applied to the memory cell transistors at the same time, for example, to perform an erase operation. Thus, as will be described in further detail below, additional methods of operation may be necessary.

The memory cell transistors and the selection transistors are electrically connected by a predetermined interconnection structure. The interconnection structure may include a first contact plug 159 and a second contact plug 240, which are sequentially stacked. The first contact plug 159 may be directly connected to an upper surface of impurity regions 140 formed on the semiconductor substrate 100. In some embodiments, the interconnection structure may include contact plug 240, another contact plug 240, and an interconnection connecting 245. The contact plug 240 is connected to an upper surface of the memory impurity region 220. Another contact plug 240 is connected to the first contact plug 159. In contrast, according to further embodiments, the interconnection structure includes a contact plug 240 that extends through the memory impurity region 220 to connect to the first contact plug 159. In this case, since the interconnection 245 located between the semiconductor patterns 175 is not needed, the semiconductor device may more efficiently use the area provided in the cell array region.

In accordance with some embodiments of the present invention, epitaxial seed patterns 177 are formed between the two adjacent ground select lines 132. The epitaxial seed patterns 177 extend from the semiconductor substrate 100 between the semiconductor patterns 175. The height of the epitaxial seed patterns 177 may be similar to that of the semiconductor patterns 175. In addition, the semiconductor substrate 100 may be a silicon wafer formed of single crystalline silicon. Similarly, the semiconductor pattern 175 and the epitaxial seed patterns 177 may be formed of single crystalline silicon.

A plurality of high voltage transistors and low voltage transistors are formed in the peripheral circuit region so as to operate the string select transistor, the ground select transistor, and/or the memory cell transistors. The high voltage transistor is formed in a high voltage transistor region (HV region), and the low voltage transistor is formed in a low voltage transistor region (LV region). The high voltage transistor has the gate insulating layer (see 123 of FIG. 17) that is thicker than the gate insulating layer (see 122 of FIG. 17) of the low voltage transistor.

As mentioned above, since the semiconductor patterns 175 have a multi-layered structure, a memory cell transistor structure including memory cell transistors formed on an upper portion of the semiconductor patterns 175 also has a multi-layered structure. Thus, multiple sets of memory cell transistors may be coupled to a same set of selection transistors in parallel. As such, the area occupied by the selection transistors may be minimized.

Bit lines 280 crossing the word lines 210 are formed on an upper portion of semiconductor patterns 175 in which the memory cell transistors are formed. The bit lines 280 are electrically connected through an upper plug 270 to the interconnection structure. The bit line 280 is connected to an impurity region 140 at one side of the string select line 131. An impurity region at the other side of the string select line 131 is connected through the interconnection structure to the memory impurity regions 220.

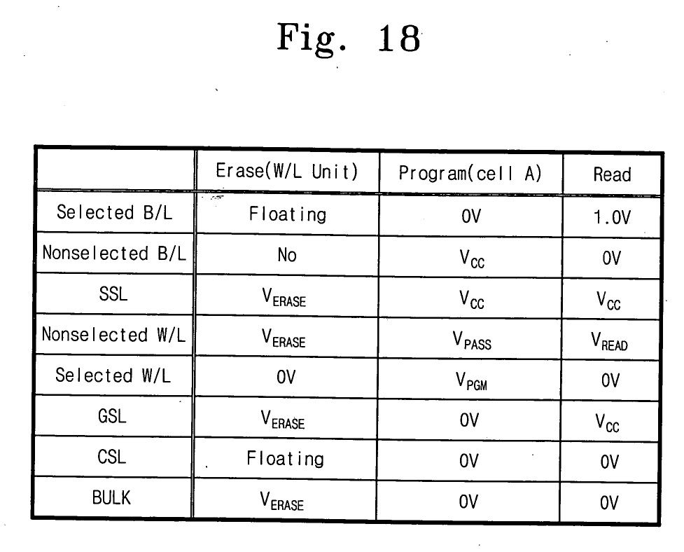

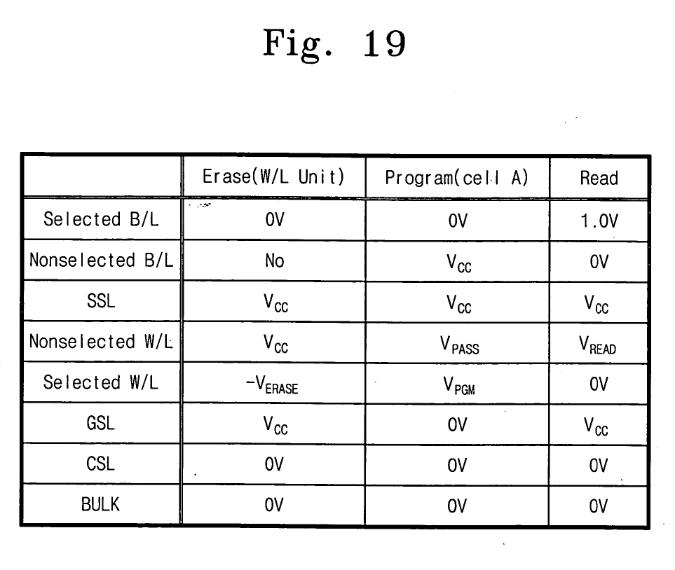

FIGS. 18 and 19 are tables illustrating operations of NAND flash memory according to some embodiments of the present invention. More particularly, FIG. 18 illustrates operations corresponding to the embodiments of FIGS. 10A and 10B, while FIG. 19 illustrates operations corresponding to FIGS. 16A and 16B. A program and read operation of the NAND flash memory according to embodiments of the present invention may be similar to those of a conventional NAND flash memory.

Referring now to FIGS. 18 and 19, during a program operation, a program voltage V_{PGM} is applied to selected word line, a pass voltage V_{PASS} is applied to non-selected word lines, and a string select voltage is applied to a string select line. In addition, 0 V is applied to the selected bit line and the ground select line, and V_{CC} is applied to non-selected bit lines. A voltage of about 0 to 0.2 V is applied to the common source line. The program voltage V_{PGM} is about 15 V to about 20 V. The pass voltage V_{PASS} is about 7 V to about 9 V. The string select voltage is generally V_{CC}. V_{CC} may be between about 1.8 V and about 3.0 V.

Since the program voltage V_{PGM} is enough to induce electron tunneling from the semiconductor pattern 175 through the memory gate insulating layer 200, a cell selected by the selected word line and bit line is programmed. In contrast, because the pass voltage V_{PASS} is smaller than the program voltage V_{PGM}, cells selected by the selected bit line and the non-selected word lines are not programmed. Similarly,

cells connected to the non-selected bit lines are not programmed when a predetermined boosting voltage V_{CC} is applied. In other words, a channel region of these memory cell transistors may have a “floating” state when 0 V is applied to the ground select line. In addition, V_{CC} and V_{PASS} are respectively applied to the string select line 131 and the non-selected word lines, and a predetermined boosting voltage is applied to the bit line in a channel under the selected word line. In the event that the boosting voltage is more than a predetermined voltage, a smaller voltage than the program voltage V_{PGM} is applied to the cells selected by non-selected bit lines and the selected word line. As a result, the cells selected by the non-selected bit lines and the selected word lines are not programmed.

During a read operation, a voltage of about 1 V is applied to a selected bit line. V_{CC} is applied to the string select line and the ground select line. A read voltage V_{READ} is applied to the non-selected word lines. A voltage of 0 V is applied to non-selected bit lines, selected word line, the common source line, and the semiconductor patterns. The read voltage V_{READ} may be approximately 5 V.

However, an erase operation may be different in embodiments of the present invention illustrated in FIGS. 1, 10A, and 10B as compared to those of FIGS. 11, 16A, and 16B.

For example, in an erase operation according to the embodiments of FIGS. 1, 10A, and 10B, an erase voltage V_{ERASE} is applied to the semiconductor pattern 175. Accordingly, electrons stored at a floating gate electrode 211 in cells connected to the selected word line may tunnel through the memory gate insulating layer 200 to the semiconductor patterns 175. The erase voltage V_{ERASE} may be about 15 V to about 22 V. During the erase operation, in order to prevent the string select transistor, the ground select transistor, and a gate insulating layer of non-selected cells from breakdown, the erase voltage V_{ERASE} may be applied to the string select line 131, the ground select line 132, and non-selected word lines. The selected bit line and the common source line 145 may be floated. In addition, the non-selected bit lines may also be floated.

However, during an erase operation according to the embodiments of FIGS. 11, 16A, and 16B, an erase voltage may not be applied to a common semiconductor pattern, as the semiconductor pattern 175 is separated into a plurality of bar-shaped patterns as described above. As such, an erase voltage (−V_{ERASE}) is applied to selected word line, a voltage of 0 V is applied to selected bit line and the common source line 145, and V_{CC} is applied to the string select line 131 and the ground select line 132. When V_{CC} is applied to the string select line 131, the ground select line 132, and non-selected word lines, the string select transistor, the ground select transistor, and the non-selected word lines may be turned on. As a result, a voltage applied to the selected bit line (0 V) is transferred to cells connected to the selected word lines. Because there is a difference between the voltage applied to the bit line and the erase voltage (−V_{ERASE}) applied to the selected word line, the cells connected to the selected word lines may be erased. The erase voltage (−V_{ERASE}) may be about −15 V to about −22 V, such that electrons stored at the floating gate electrode 211 may tunnel to the semiconductor pattern 175 through the memory gate insulating pattern 200.

As such, the erase process may be performed by a word line unit. Accordingly, it may be possible to sequentially activate selected word lines by applying the erase voltage (−V_{ERASE}) thereto in order to erase information stored in memory cells in a predetermined region. For example, the erase process may be sequentially performed starting from cells adjacent to the string select line 131.

In accordance with some embodiments of the present invention, memory cell transistors are formed on semiconductor patterns in a multi-layered structure. Accordingly, it may be possible to increase the number of memory cell transistors connected to one bit line, so that more highly integrated semiconductor memory devices can be fabricated.

In particular, according to some embodiments of the present invention directed to NAND flash memory, the number of memory cell transistors selected by a predetermined string select transistor and ground select transistor can be increased without limiting the minimum sensible current. As a result, it may be possible to fabricate more highly integrated NAND flash memory devices. Furthermore, despite technical limitations with respect to leakage current in scale-down, memory cell transistors may have a multi-layered structure. Thus, the integration density of NAND flash memory devices can be increased without increasing chip area.

In the drawings and specification, there have been disclosed embodiments of the invention and, although specific terms are employed, they are used in a generic and descriptive sense only and not for purposes of limitation, the scope of the invention being set forth in the following claims.

1-49. (canceled)

50. An integrated circuit memory device on a multi-layer substrate, comprising:
first and second selection transistors;
a first plurality of serially connected memory cell transistors on a first substrate layer and serially connected between the first and second selection transistors; and
a second plurality of serially connected memory cell transistors on a second substrate layer different from the first substrate layer and serially connected between the first and second selection transistors.

51. The device of claim 50, further comprising:
an interconnection structure;
wherein the first and second pluralities of serially connected memory cell transistors are serially connected between the first and second selection transistors by the interconnection structure, and wherein the interconnection structure electrically connects the first and second pluralities of serially connected memory cell transistors in parallel.

52. The device of claim 51, wherein the first and second selection transistors are on a third substrate layer different from the first and/or second substrate layers.

53. The device of claim 52, further comprising:
a first insulating layer between the first and second substrate layers; and
a second insulating layer between the second and third substrate layers,
wherein the interconnection structure extends through the first and second insulating layers to electrically connect the first and second pluralities of serially connected memory cell transistors and the first and second selection transistors.

54. The device of claim 53, wherein the interconnection structure comprises:
a first conductive plug electrically connecting a source/drain region of the first selection transistor to a source/drain region of a first one of the first plurality of serially connected memory cell transistors and to a source/drain region of a first one of the second plurality of serially connected memory cell transistors; and
a second conductive plug electrically connecting a source/drain region of the second selection transistor to a source/drain region of a last one of the first plurality of serially connected memory cell transistors and to a source/drain region of a last one of the second plurality of serially connected memory cell transistors.

55. The device of claim 54, wherein the first and second conductive plugs extend from the third substrate layer through the first and second substrate layers to respectively electrically connect the source/drain regions of the first and last ones of the first and second pluralities of serially connected memory cell transistors to the source/drain regions of the first and second selection transistors.

56. The device of claim 55, wherein the source/drain regions of the first and last ones of the first and second pluralities of serially connected memory cell transistors respectively extend through the first and second substrate layers to respectively electrically contact the first and second conductive plugs at sidewalls thereof.

57. The device of claim 54, wherein the first and second conductive plugs respectively include first portions extending from the third substrate layer adjacent the first and second substrate layers and second portions extending from the first portions onto the first and second substrate layers to respectively electrically connect the source/drain regions of the first and last ones of the first and second pluralities of serially connected memory cell transistors to the source/drain regions of the first and second selection transistors.

58. The device of claim 50, further comprising:
a third plurality of serially connected memory cell transistors on the first substrate layer and extending substantially parallel to the first plurality of serially connected memory cell transistors; and
an isolation layer in the first substrate layer between the first and third pluralities of serially connected memory cell transistors.

59. The device of claim 58, wherein the isolation layer extends partially into the first substrate layer to separate the first and third pluralities of serially connected memory cells, and wherein the first and third pluralities of serially connected memory cells are configured to be erased by applying an erase voltage to the first substrate layer.

60. The device of claim 58, wherein the isolation layer extends through the first substrate layer to separate the first substrate layer into at least two bar-shaped layers, and wherein ones of the first and third pluralities of serially connected memory cells are configured to be erased by applying an erase voltage to a word line connected thereto.

61. The device of claim 50, further comprising:
an epitaxial seed layer adjacent the first and second substrate layers,
wherein the first and/or second substrate layers are epitaxially grown from the epitaxial seed layer and/or the multi-layer substrate.

62. An integrated circuit memory device, comprising:
a multi-layer substrate;
first and second selection transistors on a first layer of the substrate;
a plurality of serially connected memory cell transistors on a second layer of the substrate;
an insulating layer between the first and second layers of the substrate; and
first and second interconnection plugs extending through the insulating layer from the first layer to the second layer and electrically connecting the plurality of serially connected memory cell transistors in series between the first and second selection transistors.

63. The device of claim 62, wherein the insulating layer is a first insulating layer, wherein the plurality of serially connected memory cell transistors is a first plurality of serially connected memory cell transistors, and further comprising:
a second plurality of serially connected memory cell transistors on a third layer of the substrate; and
a second insulating layer between the second and third layers of the substrate,
wherein the first and second interconnection plugs further extend through the second insulating layer to electrically connect the first plurality of serially connected memory cell transistors in parallel with the second plurality of serially connected memory cell transistors.

64. A multi-layer integrated circuit memory device including first and second selection transistors, a first plurality of serially connected memory cell transistors on a first substrate layer, and a second plurality of serially connected memory cell transistors on a second substrate layer, comprising:
an interconnection structure electrically connecting the first plurality of memory cell transistors in parallel with the second plurality of memory cell transistors and in series between the first and second selection transistors.

65. The device of claim 64, further comprising:
a first plurality of word lines respectively electrically connected to the first plurality of serially connected memory cell transistors on the first substrate layer;
a second plurality of word lines respectively electrically connected to the second plurality of serially connected memory cell transistors on the second substrate layer; and
a bit line electrically connected to one of the first and second selection transistors by the interconnection structure.

66. A method of fabricating an integrated circuit memory device, the method comprising:
forming first and second selection transistors on a first substrate layer;
forming a plurality of serially connected memory cell transistors on a second substrate layer;
forming an insulating layer between the first and second layers of the substrate; and
forming first and second interconnection plugs extending through the insulating layer from the first substrate layer to the second substrate layer,
wherein the first and second interconnection plugs electrically connect the plurality of serially connected memory cell transistors in series between the first and second selection transistors.

67. The method of claim 66, wherein the insulating layer is a first insulating layer, and wherein the plurality of serially connected memory cell transistors is a first plurality of serially connected memory cell transistors, the method further comprising:
forming a second plurality of serially connected memory cell transistors on a third substrate layer; and
forming a second insulating layer between the second and third substrate layers,
wherein forming the first and second interconnection plugs further comprises forming the first and second interconnection plugs to extend through the second insulating layer to electrically connect the first plurality of serially connected memory cell transistors in parallel with the second plurality of serially connected memory cell transistors.

68. The method of claim 67, wherein forming the first and second pluralities of serially connected memory cell transistors comprises:
forming the first and second pluralities of serially connected memory cell transistors using a same mask pattern.

69. The method of claim 67, wherein forming the first and second interconnection plugs comprises:
forming the first interconnection plug extending from a source/drain region of the first selection transistor on the first substrate layer through the second and third substrate layers to electrically connect to a source/drain region of a first one of the first plurality of serially connected memory cell transistors and to a source/drain region of a first one of the second plurality of serially connected memory cell transistors; and
forming the second interconnection plug extending from a source/drain region of the second selection transistor on the first substrate layer through the second and third substrate layers to electrically connect to a source/drain region of a last one of the first plurality of serially connected memory cell transistors and to a source/drain region of a last one of the second plurality of serially connected memory cell transistors.

70. The method of claim 67, wherein forming the first and second interconnection plugs comprises:
forming the first interconnection plug including a first portion extending from a source/drain region of the first selection transistor on the first substrate layer adjacent the second and third substrate layers and second portions extending from the first portion onto the second and third substrate layers to electrically connect to a source/drain region of a first one of the first plurality of serially connected memory cell transistors and to a source/drain region of a first one of the second plurality of serially connected memory cell transistors; and
forming the second interconnection plug including a first portion extending from a source/drain region of the second selection transistor on the first substrate layer adjacent the second and third substrate layers and second portions extending from the first portion onto the second and third substrate layers to electrically connect to a source/drain region of a last one of the first plurality of serially connected memory cell transistors and to a source/drain region of a last one of the second plurality of serially connected memory cell transistors.

71. The method of claim 67, further comprising:
forming an epitaxial seed layer on the first substrate layer,
wherein the second and/or third substrate layers are epitaxially grown from the first substrate layer and/or the epitaxial seed layer.
